(19) United States
(12) Patent Application Publication
(10) Pub. No.: US 2015/0333244 A1
(43) Pub. Date: Nov. 19, 2015

(54) THERMOELECTRIC GENERATOR

(71) Applicant: Yojiro IRIYAMA, Toyota-shi, Aichi-ken (JP)

(72) Inventor: Yojiro IRIYAMA, Toyota-shi, Aichi-ken (JP)

(73) Assignee: TOYOTA JIDOSHA KABUSHIKI KAISHA, Toyota-shi, Aichi-ken (JP)

(21) Appl. No.: 14/410,254

(22) PCT Filed: Sep. 23, 2013
(86) PCT No.: PCT/IB2013/002077

§ 371 Date: Dec. 22, 2014

(30) Foreign Application Priority Data
Sep. 27, 2012 (JP) 2012-214157

(51) Int. Cl. H01L 35/30; H01L 35/32

(52) U.S. Cl. CPC H01L 35/30; H01L 35/32

(57) ABSTRACT

A thermoelectric generator for mounting on an internal combustion engine, includes a selecting device, an exhaust pipe, a thermoelectric conversion module, a regulating valve and a controller. The selecting device is configured to select a first operation mode and a second operation mode. The exhaust pipe includes a first exhaust passage and a second exhaust passage. The regulating valve configured to adjust a flow rate of the exhaust gas. The controller is configured to adjust an opening degree of the regulating valve such that the flow rate of the exhaust gas flowing through the second exhaust passage reduces as compared to that in the first operation mode, on the condition that the second operation mode is selected by the selecting device after completion of warm-up of the internal combustion engine.

### BACKGROUND OF THE INVENTION

1. Field of the Invention

The invention relates to a thermoelectric generator and, more particularly, to a thermoelectric generator that thermoelectrically generates electric power by utilizing heat of exhaust gas that is emitted from an internal combustion engine.

2. Description of Related Art

Generally, a thermoelectric generator generates electric power by utilizing a temperature difference between a high-temperature portion of a thermoelectric conversion module, on which exhaust gas emitted from an internal combustion engine acts, and a low-temperature portion of the thermoelectric conversion module, on which coolant acts.

There is such a thermoelectric generator that adjusts the flow rate of exhaust gas passing through the thermoelectric generator to a predetermined value or lower by driving a flow regulating valve, which regulates the flow rate of exhaust gas passing through the thermoelectric generator, in a valve closing direction when an accelerator operation amount is larger than or equal to a predetermined value in order to prevent damage to a thermoelectric conversion module due to high-temperature exhaust gas during high-load operation of a vehicle (for example, see Japanese Patent Application Publication No. 11-229867 (JP 11-229867 A)).

The thermoelectric generator is able to decrease the flow rate of exhaust gas that acts on the thermoelectric conversion module during high-load operation of the vehicle, so it is possible to inhibit damage to the thermoelectric conversion module.

However, in such an existing thermoelectric generator. for example, adjusting the opening degree of a flow regulating valve between a case where a mode in which the torque of an internal combustion engine is increased for the same accelerator operation amount like a power mode is selected and a case where the mode is not selected is not taken into consideration. Thus, it is not possible to keep a balance between the output performance of the internal combustion engine and the power generation efficiency of the thermoelectric generator.

For example, if the flow regulating valve is driven in the valve closing direction at the time when the power mode is not selected, the amount of heat that acts on the thermoelectric conversion module reduces and, as a result, the power generation efficiency decreases. On the other hand, if the flow regulating valve is driven in the valve closing direction at the time when the power mode is selected, the back pressure of the internal combustion engine increases and, as a result, the output performance of the internal combustion engine may decreases.

### SUMMARY OF THE INVENTION

The invention provides a thermoelectric generator that is able to change the opening degree of a regulating valve on the basis of an operation mode of an internal combustion engine, that is able to suppress a decrease in the output performance of the internal combustion engine and that is able to improve power generation efficiency.

An aspect of the invention provides a thermoelectric generator mounted on an internal combustion engine. The thermoelectric generator includes: a selecting device configured to select a first operation mode and a second operation mode in which a torque of the internal combustion engine for the same accelerator operation amount is adjusted to a torque larger than that in the first operation mode; an exhaust pipe including a first exhaust passage to which exhaust gas emitted from the internal combustion engine is introduced and a second exhaust passage that communicates with the first exhaust passage; a thermoelectric conversion module including a high-temperature portion and a low-temperature portion, the high-temperature portion facing the second exhaust passage, the low-temperature portion facing a cooling pipe through which cooling medium flows, the thermoelectric conversion module being configured to thermoelectrically generate electric power on the basis of a temperature difference between the high-temperature portion and the low-temperature portion; a regulating valve provided at the exhaust pipe and configured to adjust a flow rate of the exhaust gas flowing through the second exhaust passage by adjusting an opening degree of the first exhaust passage; and a controller configured to adjust an opening degree of the regulating valve such that the flow rate of the exhaust gas flowing through the second exhaust passage reduces as compared to that in the first operation mode, on the condition that the second operation mode is selected by the selecting device after completion of warm-up of the internal combustion engine.

The controller of the thermoelectric generator adjusts the opening degree of the regulating valve such that the flow rate of the exhaust gas flowing through the second exhaust passage reduces as compared to that in the first operation mode when the second operation mode in which the torque of the internal combustion engine is increased is selected after completion of warm-up of the internal combustion engine, so it is possible to increase the flow rate of the exhaust gas flowing through the first exhaust passage by increasing the opening degree of the first exhaust passage. Therefore, it is possible to prevent an increase in the back pressure of the internal combustion engine, so it is possible to suppress a decrease in the output performance of the internal combustion engine.

In addition, the controller adjusts the opening degree of the regulating valve such that the flow rate of the exhaust gas flowing through the second exhaust passage increases as compared to that in the second operation mode when the first operation mode in which the torque of the internal combustion engine is reduced as compared to that in the second operation mode is selected after completion of warm-up of the internal combustion engine, so it is possible to increase the amount of heat of the exhaust gas, which acts on the high-temperature portion of the thermoelectric conversion module. Therefore, it is possible to improve the power generation efficiency of the thermoelectric conversion module.

In addition, the controller does not adjust the opening degree of the regulating valve such that the flow rate of the exhaust gas flowing through the second exhaust passage reduces even when the second operation mode is selected before completion of warm-up of the internal combustion engine, so it is possible to prevent a decrease in the amount of heat of the exhaust gas, which acts on the high-temperature portion. Therefore, it is possible to facilitate heat exchange between the exhaust gas and the cooling medium, so it is possible to achieve early warm-up of the internal combustion engine.

In the above thermoelectric generator, the controller may be configured to variably set the flow rate of the exhaust gas introduced to the second exhaust passage on the basis of the accelerator operation amount when one of the first operation mode and the second operation mode is selected, and the controller may be configured to execute flow rate control such that the flow rate of the exhaust gas flowing through the second exhaust passage reduces as compared to that in the first operation mode as the accelerator operation amount increases when the second operation mode is set.

The controller of the thermoelectric generator executes flow rate control such that the flow rate of the exhaust gas flowing through the second exhaust passage reduces as compared to that in the first operation mode as the accelerator operation amount increases when the second operation mode is set. Therefore, when the internal combustion engine rotates at a high speed and operates at a high load, it is possible to prevent an increase in the back pressure of the internal combustion engine, so it is possible to further suppress a decrease in the output performance of the internal combustion engine. Thus, it is possible to thermoelectrically generate electric power while maintaining the output performance of the internal combustion engine.

In the above thermoelectric generator, the controller may be configured to adjust the opening degree of the regulating valve such that the flow rate of the exhaust gas flowing through the second exhaust passage reduces as compared to that when the state of charge of the battery is smaller than the predetermined level, on the condition that the first operation mode is selected and a state of charge of a battery, which is charged with electric power generated by the thermoelectric generator, is larger than or equal to a predetermined level.

The controller of the thermoelectric generator adjusts the opening degree of the regulating vale such that the flow rate of the exhaust gas flowing through the second exhaust passage reduces when the first operation mode is selected and the state of charge of the battery is larger than or equal to the predetermined level, so, for example, when the state of charge of the battery is an upper limit value, it is possible to reduce the amount of heat of the exhaust gas, which acts on the high-temperature portion. Therefore, it is possible to prevent useless charging operation.

In the above thermoelectric generator, the cooling medium flowing through the cooling pipe may be coolant that cools the internal combustion engine, and the controller may be configured to adjust the opening degree of the regulating valve such that the flow rate of the exhaust gas flowing through the second exhaust passage reduces as compared to that when the temperature of the coolant is lower than the predetermined temperature, on the condition that a temperature of the coolant is higher than or equal to a predetermined temperature.

The regulating valve control device of the thermoelectric generator adjusts the opening degree of the regulating valve such that the flow rate of the exhaust gas flowing through the second exhaust passage reduces as compared to that when the temperature of the coolant is lower than the predetermined temperature on the condition that the temperature of the coolant is higher than or equal to the predetermined temperature. Therefore, when there is a possibility that the temperature of the coolant becomes higher than or equal to the predetermined temperature and the coolant boils, it is possible to reduce the amount of heat of the exhaust gas, which acts on the high-temperature portion, so it is possible to prevent overheat of the internal combustion engine by preventing boiling of the coolant.

In the above thermoelectric generator, the exhaust pipe may include a first exhaust pipe and a second exhaust pipe, the first exhaust pipe having the first exhaust passage, the second exhaust pipe provided coaxially with the first exhaust pipe, the second exhaust pipe having the second exhaust passage that communicates with the first exhaust passage, the high-temperature portion of the thermoelectric conversion module may face the second exhaust pipe, the low-temperature portion may face the cooling pipe provided coaxially with the second exhaust pipe, and the regulating valve may be provided at the first exhaust pipe and configured to adjust the flow rate of the exhaust gas flowing through the second exhaust passage by adjusting the opening degree of the first exhaust passage.

The thermoelectric generator is able to increase the amount of heat that acts on the high-temperature portion through an increase in the flow rate of the exhaust gas introduced to the second exhaust passage of the second exhaust pipe by reducing the opening degree of the first exhaust passage of the first exhaust pipe with the use of the regulating valve, so it is possible to improve the power generation efficiency of the thermoelectric conversion module.

In addition, it is possible to increase the flow rate of the exhaust gas emitted through the first exhaust passage by increasing the opening degree of the first exhaust passage of the first exhaust pipe with the use of the regulating valve, so it is possible to suppress a decrease in the exhaust emission performance of the internal combustion engine by decreasing the back pressure of the internal combustion engine.

In addition, the first exhaust pipe, the second exhaust pipe and the cooling pipe are provided coaxially with one another, so it is possible to reduce the size of the thermoelectric generator, and it is possible to improve the vehicle mountability of the thermoelectric generator.

According to the aspect of the invention, it is possible to provide the thermoelectric generator that is able to change the opening degree of the regulating valve on the basis of the operation mode of the internal combustion engine, that is able to suppress a decrease in the output performance of the internal combustion engine and that is able to improve power generation efficiency.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is a view that shows a thermoelectric generator according to a first embodiment of the invention and is a schematic configuration view of an internal combustion engine that includes the thermoelectric generator;

FIG. 2 is a view that shows the thermoelectric generator according to the first embodiment of the invention and is a side cross-sectional view of the thermoelectric generator;

FIG. 3 is a view that shows the thermoelectric generator according to the first embodiment of the invention and is a perspective view of each thermoelectric conversion module;

FIG. 4 is a view that shows the thermoelectric generator according to the first embodiment of the invention and is a cross-sectional view taken along the line IV-IV in FIG. 2:

FIG. 5 is a view that shows the thermoelectric generator according to the first embodiment of the invention and is a block diagram of a control circuit of the internal combustion engine and thermoelectric generator;

FIG. 6 is a graph that shows the correlation between an accelerator operation amount and an opening degree of an open/close valve in a P mode and a non-P mode in the thermoelectric generator according to the first embodiment of the invention:

FIG. 7 is a view that shows a flowchart of an open/close valve control program in the thermoelectric generator according to the first embodiment of the invention;

FIG. 8 is a graph that shows another correlation between an accelerator operation amount and an opening degree of the open/close valve in the P mode and the non-P mode in the thermoelectric generator according to the first embodiment of the invention;

FIG. 9 is a view that shows a thermoelectric generator according to a second embodiment of the invention and is a schematic configuration view of an internal combustion engine that includes the thermoelectric generator;

FIG. 10 is a view that shows the thermoelectric generator according to the second embodiment of the invention and is a side cross-sectional view of the thermoelectric generator; and

FIG. 11 is a view that shows the thermoelectric generator according to the second embodiment of the invention and is a cross-sectional view taken along the line XI-XI in FIG. 10.

### DETAILED DESCRIPTION OF EMBODIMENTS

Hereinafter, embodiments of a thermoelectric generator according to the invention will be described with reference to the accompanying drawings. In the present embodiments, description will be made on a case where the thermoelectric generator is applied to a water-cooled multi-cylinder internal combustion engine, such as a four-cycle gasoline engine (hereinafter, simply referred to as engine), mounted on a vehicle, such as an automobile. The engine is not limited to the gasoline engine.

### First Embodiment

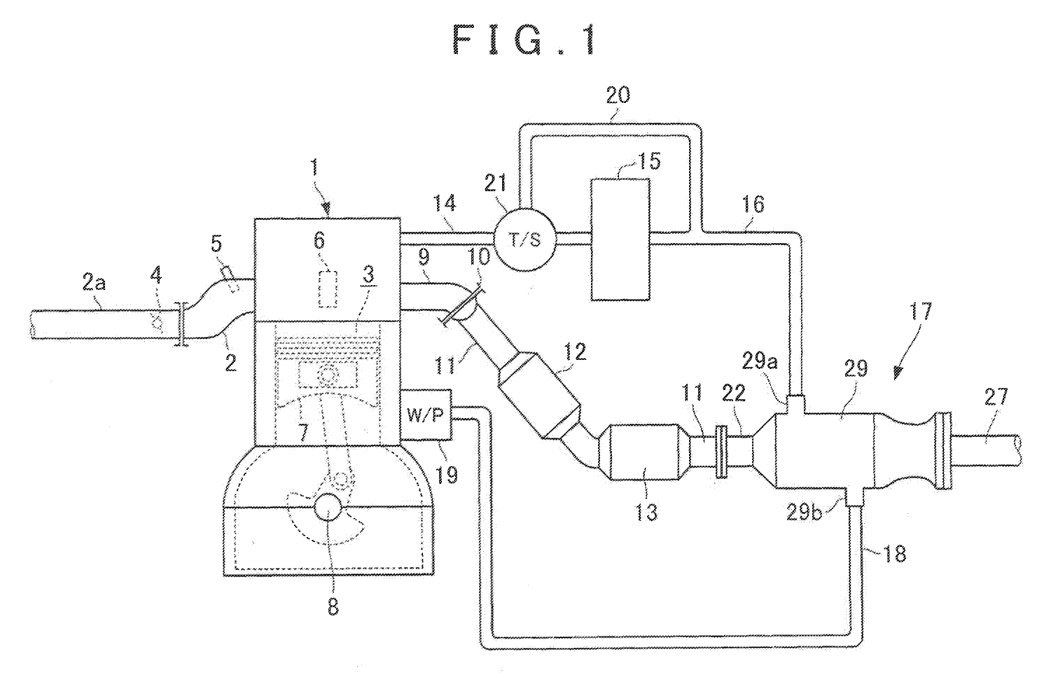

FIG. 1 to FIG. 8 are views that show a thermoelectric generator according to a first embodiment of the invention. First, the configuration will be described.

As shown in FIG. 1, an engine 1 serves as an internal combustion engine mounted on a vehicle, such as an automobile. The engine 1 supplies air-fuel mixture into combustion chambers and is combusted, and then emits exhaust gas generated through the combustion to the atmosphere through an exhaust system. The air-fuel mixture is a mixture of air supplied from an intake system with fuel supplied from a fuel supply system at an appropriate air-fuel ratio.

The intake system is formed of an intake manifold 2 and an intake pipe 2a. The intake manifold 2 is connected to the engine 1. The intake pipe 2a is connected to the intake manifold 2. The intake pipe 2a cleans air, taken in through an air duct (not shown) provided at the upstream side of the intake pipe 2a, with the use of an air cleaner (not shown) and then introduces the air into the intake manifold 2.

The intake manifold 2 distributes air, introduced from the intake pipe 2a, among the combustion chambers 3 of cylinders of the engine 1, and includes branch pipes in number corresponding to the number of the cylinders of the engine 1. For example, in the case of a four-cylinder engine, the four branch pipes are provided. However, the number of the cylinders of the engine 1 is not specifically limited to four. A throttle valve 4 is provided in the intake pipe 2a. The throttle valve 4 adjusts the amount of intake air introduced into the combustion chambers 3. A fuel injection valve 5 is provided in each branch pipe of the intake manifold 2. Each fuel injection valve 5 injects and supplies fuel to a corresponding one of the combustion chambers 3 of the engine 1.

When fuel is injected from any one of the fuel injection valves 5 to a corresponding one of the combustion chambers 3, air-fuel mixture formed of the fuel and air introduced from the intake pipe 2a to the intake manifold 2 is filled inside the corresponding combustion chamber 3, and the air-fuel mixture is combusted through ignition of an ignition plug 6 provided at the corresponding cylinder. A corresponding one of pistons 7 of the engine 1 reciprocally moves due to combustion energy at this time, and the reciprocal motion of the piston 7 is converted to the rotational motion of a crankshaft 8 of the engine 1.

On the other hand, the exhaust system is formed of an exhaust manifold 9 and an exhaust pipe 11. The exhaust manifold 9 is connected to the engine 1. The exhaust pipe 11 is coupled to the exhaust manifold 9 via a spherical joint 10. An exhaust passage is formed inside the exhaust manifold 9 and inside the exhaust pipe 11.

The spherical joint 10 allows an appropriate amount of pivot between the exhaust manifold 9 and the exhaust pipe 11, and functions not to transmit the vibration and movement of the engine 1 to the exhaust pipe 11 or to transmit the vibration and movement of the engine 1 to the exhaust pipe 11 by damping the vibration and movement. Two catalysts 12, 13 are installed in series with each other in the exhaust pipe 11. Exhaust gas is purified by the catalysts 12, 13.

Between the catalysts 12, 13, the catalyst 12 installed at the upstream side in an exhaust direction of exhaust gas in the exhaust pipe 11 is a so-called start catalyst (S/C), and the catalyst 13 installed at the downstream side in the exhaust direction of exhaust gas in the exhaust pipe 11 is a so-called main catalyst (M/C) or underfloor catalyst (U/F).

These catalysts 12, 13 each are, for example, formed of a three-way catalyst. The three-way catalyst exercises purifying effect such that carbon monoxide (CO), hydrocarbons (HC) and nitrogen oxides (NOx) are collectively changed to harmless components through chemical reaction.

A water jacket is formed inside the engine 1. A cooling fluid (hereinafter, simply referred to as coolant) that serves as a cooling medium called long life coolant (LLC) is filled in the water jacket.

The coolant is delivered through a delivery pipe 14 connected to the engine 1, and is supplied to a radiator 15, and is then introduced from the radiator 15 to an upstream-side pipe 16. The coolant introduced to the upstream-side pipe 16 is introduced to a coolant pipe (described later) of the thermoelectric generator 17, and is returned to the engine 1 via a downstream-side pipe 18.

The radiator 15 cools coolant, circulated by a water pump 19, through heat exchange with outside air. A bypass pipe 20 is coupled to the delivery pipe 14. A thermostat 21 is interposed between the bypass pipe 20 and the delivery pipe 14. The amount of coolant flowing through the radiator 15 and the amount of coolant flowing through the bypass pipe 20 are adjusted by the thermostat 21.

For example, warm-up of the engine 1 is facilitated by increasing the amount of coolant flowing through the bypass pipe 20 during warm-up operation of the engine 1, and the cooling performance of the engine 1 is improved by reducing the amount of coolant flowing through the bypass pipe 20 or not bypassing coolant toward the bypass pipe 20 after completion of warm-up of the engine 1.

On the other hand, the thermoelectric generator 17 is provided in the exhaust system of the engine 1. The thermoelectric generator 17 recovers heat of exhaust gas emitted from the engine 1, and converts thermal energy of exhaust gas to electric energy.

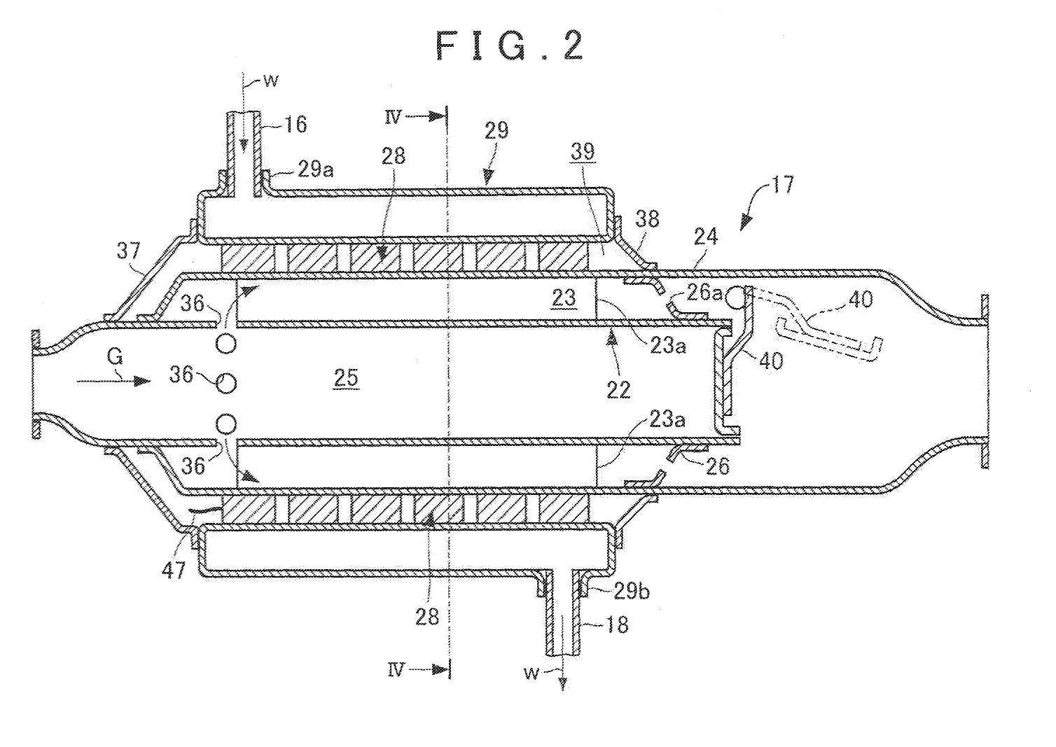

As shown in FIG. 2, the thermoelectric generator 17 includes an inner pipe 22 and an outer pipe 24. The inner pipe 22 serves as a first exhaust pipe to which exhaust gas, emitted from the engine 1, is introduced. The outer pipe 24 is provided outside the inner pipe 22, and forms a heat receiving passage 23 between the outer pipe 24 and the inner pipe 22. The outer pipe 24 serves as a second exhaust pipe. The heat receiving passage 23 serves as a second exhaust passage. An exhaust pipe according to the invention is formed of the inner pipe 22 and the outer pipe 24.

The upstream end of the inner pipe 22 is coupled to the exhaust pipe 11. A bypass passage 25 that serves as a first exhaust passage is formed inside the inner pipe 22. Exhaust gas is introduced from the exhaust pipe 11 to the bypass passage 25. The inner pipe 22 is fixed to the outer pipe 24 via a support member 26, and the downstream end of the outer pipe 24 is coupled to a tail pipe 27 (see FIG. 1).

Therefore, exhaust gas G emitted from the engine 1 to the bypass passage 25 of the inner pipe 22 through the exhaust pipe 11 is emitted to the tail pipe 27 through the bypass passage 25, and is then emitted from the tail pipe 27 to outside air. The thermoelectric generator 17 includes a plurality of thermoelectric conversion modules 28 and a coolant pipe 29. The plurality of thermoelectric conversion modules 28 are arranged in the exhaust direction of the exhaust gas G. The coolant pipe 29 serves as a cylindrical cooling pipe.

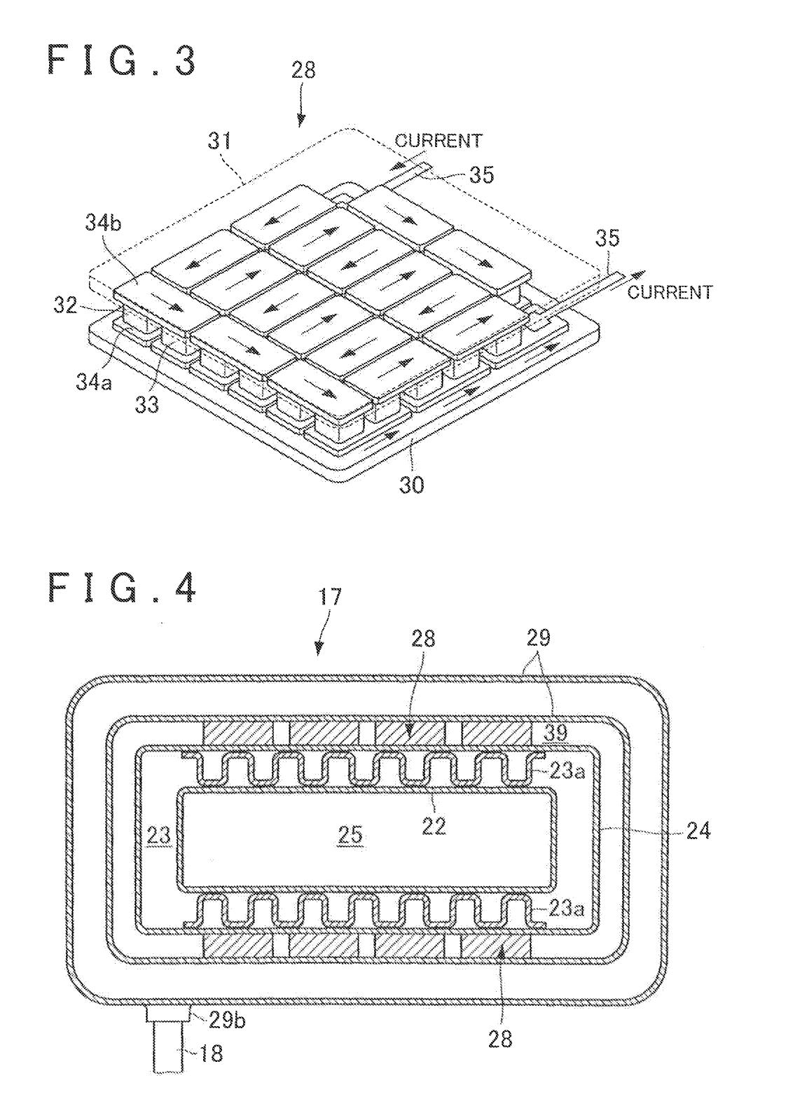

As shown in FIG. 3, in each of the thermoelectric conversion modules 28, a plurality of N-type thermoelectric conversion elements 32 and P-type thermoelectric conversion elements 33 are arranged between a heat receiving substrate 30 and a heat dissipating substrate 31. The heat receiving substrate 30 is made of electrical insulating ceramics and constitutes a high-temperature portion. The heat dissipating substrate 31 is made of electrical insulating ceramics and constitutes a low-temperature portion. The plurality of N-type thermoelectric conversion elements 32 and P-type thermoelectric conversion elements 33 generate electromotive force based on a temperature difference due to the Seebeck effect. The N-type thermoelectric conversion element 32 and the P-type thermoelectric conversion element 33 are alternately connected in series with each other via an electrode 34a or an electrode 34b. Any adjacent two of the thermoelectric conversion modules 28 are electrically coupled to each other via a line 35.

In each of the thermoelectric conversion modules 28, the heat receiving substrate 30 laces the outer pipe 24 and is in contact with the outer pipe 24, and the heat dissipating substrate 31 faces the coolant pipe 29 and is in contact with the coolant pipe 29. The thermoelectric conversion modules 28 are arranged in parallel with one another in the exhaust direction of the exhaust gas G. In FIG. 2, each thermoelectric conversion module 28 shown in FIG. 3 is shown in a simplified view.

Each thermoelectric conversion module 28 thermoelectrically generates electric power on the basis of the heat difference between the heat receiving substrate 30 and the heat dissipating substrate 31, and supplies (charges) an auxiliary battery (described later) with the generated electric power via a cable 47.

Each thermoelectric conversion module 28 has a substantially square plate shape, and needs to be in close contact with the outer pipe 24 and the coolant pipe 29 in between, so the inner pipe 22, the outer pipe 24 and the coolant pipe 29 are formed in a polygonal shape in cross section.

The inner pipe 22, the outer pipe 24 and the coolant pipe 29 may be formed in a circular shape in cross section. In this case, the heat receiving substrate 30, the heat dissipating substrate 31, and the like, of each thermoelectric conversion module 28 just need to be curved. The coolant pipe 29 includes a coolant introduction portion 29a and a coolant drain portion 29b. The coolant introduction portion 29a is coupled to the upstream-side pipe 16. The coolant drain portion 29b is coupled to the downstream-side pipe 18.

In the coolant pipe 29, the coolant introduction portion 29a is provided on the upstream side in the exhaust direction with respect to the coolant drain portion 29b such that coolant W introduced to the coolant pipe 29 through the coolant introduction portion 29a flows in the same direction as the exhaust direction of the exhaust gas G.

On the other hand, the inner pipe 22 has a plurality of communication holes 36, and the communication holes 36 provide fluid communication between the bypass passage 25 and the heat receiving passage 23. The communication holes 36 are formed at set intervals in the circumferential direction of the inner pipe 22. The communication holes 36 are not limited to the configuration that the communication holes 36 are formed at set intervals.

Communication holes 26a are formed in the support member 26 at set intervals in the circumferential direction of the support member 26. The heat receiving passage 23 communicates with the tail pipe 27 through the communication holes 26a. The communication holes 26a are not limited to the configuration that the communication holes 26a are formed at set intervals.

A plate 37 is provided so as to span between the upstream side of the coolant pipe 29 and the inner pipe 22. A plate 38 is provided so as to span between the downstream side of the coolant pipe 29 and the outer pipe 24. Therefore, the thermoelectric conversion modules 28 are accommodated in a module chamber 39 that is a hermetically sealed space surrounded by the plates 37, 38, the inner peripheral portion of the coolant pipe 29, the outer peripheral portion of the inner pipe 22 and the outer peripheral portion of the outer pipe 24.

As shown in FIG. 4, comb-shaped heat transfer members 23a are provided in the heat receiving passage 23. Each heat transfer member 23a is bent along the width direction of the inner pipe 22 and outer pipe 24 and extends in the longitudinal direction of the inner pipe 22 and outer pipe 24, and is in contact with the outer periphery of the inner pipe 22 and the inner periphery of the outer pipe 24 such that upper end bent portions face the heat receiving substrates 30.

Therefore, heat of exhaust gas flowing through the heat receiving passage 23 propagates through the heat transfer members 23a and is efficiently transferred to the heat receiving substrates 30.

As shown in FIG. 2, an open/close valve 40 that serves as a regulating valve is provided in the inner pipe 22. The open/close valve 40 is provided at the downstream end of the inner pipe 22, and is pivotably connected to the outer pipe 24 so as to open or close the inner pipe 22. The open/close valve 40 is opened or closed by an actuator 41 that serves as an open/close control device.

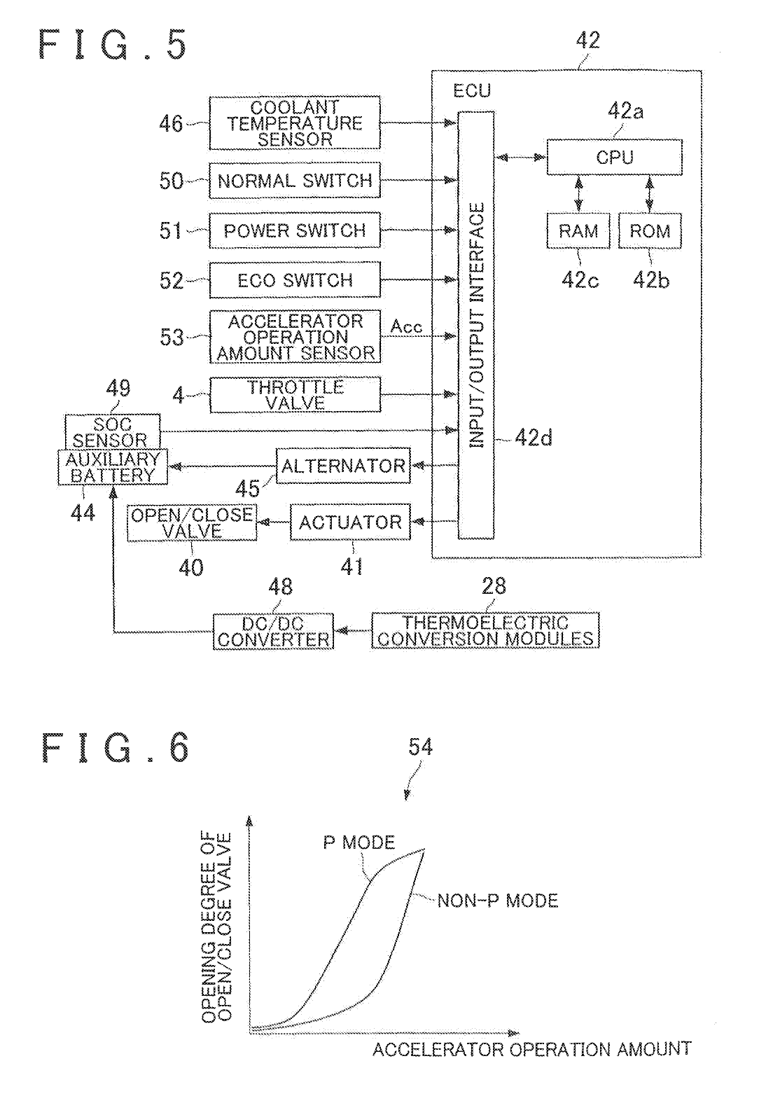

As shown in FIG. 5, the actuator 41 is controlled by an electronic control unit (ECU) 42. The actuator 41 executes open/close control over the open/close valve 40 on the basis of a drive signal from the ECU 42.

That is, the actuator 41 changes the opening degree of the open/close valve 40 through duty control over exciting current, and the ECU 42 executes duty control over the actuator 41.

Therefore, the flow rate of exhaust gas introduced from the bypass passage 25 to the heat receiving passage 23 is increased as the open/close valve 40 closes the bypass passage 25; whereas the flow rate of exhaust gas introduced from the bypass passage 25 to the heat receiving passage 23 is decreased as the opening degree of the bypass passage 25 increases with an increase in the amount of opening of the open/close valve 40 by opening the open/close valve 40.

In FIG. 5, the ECU 42 is formed of an electronic control circuit including a central processing unit (CPU) 42a, a read only memory (ROM) 42b, a random access memory (RAM) 42c, an input/output interface 42d, and the like. The ECU 42 executes open/close control over the open/close valve 40 on the basis of an open/close valve control program stored in the ROM 42b.

As shown in FIG. 5, an alternator 45 is provided at the engine 1. The alternator 45 charges an auxiliary battery 44 that serves as a battery. The alternator 45 generates electric power by being driven by the engine 1. Thus, the alternator 45 charges the auxiliary battery 44.

A coolant temperature sensor 46 is provided at the engine 1. The coolant temperature sensor 46 detects the temperature of coolant (hereinafter, coolant temperature) flowing through the engine, and outputs detected information to the ECU 42. The coolant temperature sensor 46 may be provided at the upstream-side pipe 16, the downstream-side pipe 18, or the like.

The cable 47 of each thermoelectric conversion module 28 is connected to the auxiliary battery 44 via a DC/DC converter 48. The DC/DC converter 48 adjusts direct-current voltage output from the thermoelectric conversion modules 28 and applies the direct-current voltage to the auxiliary battery 44, thus charging the auxiliary battery 44.

A state-of-charge (SOC) sensor 49 is provided at the auxiliary battery 44. The SOC sensor 49 detects the state of charge of the auxiliary battery 44, and outputs an electric signal based on the state of charge to the ECU 42. The ECU 42 calculates the state of charge of the auxiliary battery 44 on the basis of the signal from the SOC sensor 49.

A normal switch 50, a power switch 51 and an eco switch 52 are connected to the ECU 42.

The normal switch 50 is a switch for setting an operation state of the engine 1 to a normal mode. The ECU 42 adjusts the opening degree of the throttle valve 4 on the basis of the operation amount of an accelerator pedal when the normal switch 50 is selected.

Specifically, a normal mode map is stored in the ROM 42b of the ECU 42. A throttle opening degree and an accelerator operation amount during the normal mode are associated with each other in the normal mode map. When the ECU 42 receives an accelerator operation amount signal Acc from an accelerator operation amount sensor 53 that detects the operation amount of the accelerator pedal, the ECU 42 consults the normal mode map, and sets the opening degree of the throttle valve 4 on the basis of the accelerator operation amount.

At this time, intake air based on the opening degree of the throttle valve 4 is introduced to each combustion chamber 3, and fuel based on the intake air amount is injected from the corresponding fuel injection valve 5, with the result that the torque of the engine 1 is output.

The power switch 51 is a switch for selecting a power mode that gives priority to the output performance of the engine 1. When the power switch 51 is selected, the torque of the engine 1 for the same accelerator operation amount is increased.

When the power switch 51 is operated and a signal is input from the power switch 51 to the ECU 42, the ECU 42 increases the opening degree of the throttle valve 4 as compared to the opening degree during the normal mode such that the torque of the engine 1 for the same accelerator operation amount as that in the normal mode increases.

A power mode map is stored in the ROM 42b of the ECU 42. A throttle opening degree and an accelerator operation amount during the power mode are associated with each other in the power mode map. The ECU 42 consults the power mode map on the basis of the accelerator operation amount signal Acc input from the accelerator operation amount sensor 53 at the time when the power mode is selected, and opens the throttle valve 4 at an opening degree larger than the opening degree of the throttle valve 4 during the normal mode.

At this time, intake air based on the opening degree of the throttle valve 4 is introduced to each combustion chamber 3, and fuel based on the intake air amount is injected from the corresponding fuel injection valve 5, with the result that the torque of the engine 1 increases for the same accelerator operation amount as that in the normal mode, and the amount of emission of exhaust gas increases.

The eco switch 52 is a switch for selecting an eco mode that gives priority to fuel economy of the engine 1. When the eco switch 52 is selected, the torque of the engine 1 for the same accelerator operation amount is set so as to be reduced.

An eco mode map is stored in the ROM 42b of the ECU 42. A throttle opening degree and an accelerator operation amount during the eco mode are associated with each other in the eco mode map. The ECU 42 consults the eco mode map on the basis of the accelerator operation amount signal Acc input from the accelerator operation amount sensor 53 at the time when the eco mode is selected, and opens the throttle valve 4 at an opening degree smaller than the opening degree of the throttle valve 4 during the normal mode.

At this time, intake air based on the opening degree of the throttle valve 4 is introduced to each combustion chamber 3, and fuel based on the intake air amount is injected from the corresponding fuel injection valve 5, with the result that the torque of the engine 1 reduces for the same accelerator operation amount as that in the normal mode, and the amount of emission of exhaust gas reduces.

In the thermoelectric generator 17 according to the present embodiment, the normal mode and the eco mode (hereinafter, referred to as non-P mode) constitute a first operation mode. The power mode (hereinafter, simply referred to as P mode) constitutes a second operation mode in which the torque of the engine 1 for the same accelerator operation amount as that in the non-P mode is adjusted to a torque larger than that in the non-P mode.

In the thermoelectric generator 17 according to the present embodiment, the normal switch 50, the power switch 51 and the eco switch 52 constitute a selecting device. The ECU 42 determines whether warm-up of the engine 1 has been completed on the basis of the detected information from the coolant temperature sensor 46. On the condition that the power switch 51 is selected after completion of warm-up of the engine, the ECU 42 adjusts the opening degree of the open/close valve 40 such that the flow rate of exhaust gas flowing through the heat receiving passage 23 reduces as compared to that when the normal switch 50 or the eco switch 52 is selected. The ECU 42 and the actuator 41 constitute a regulating valve control device (can be regarded as a controller).

As shown in FIG. 6, an open/close valve opening degree map 54 is stored in the ROM 42b of the ECU 42. An accelerator operation amount and an opening degree of the open/close valve 40 are associated with each other in the open/close valve opening degree map 54. In the open/close valve opening degree map 54, the opening degree of the open/close valve 40 in the P mode is set so as to be larger than the opening degree of the open/close valve 40 in the non-P mode for the same accelerator operation amount. In any of the P mode and the non-P mode, the characteristic is set such that the opening degree of the open/close valve 40 increases as the accelerator operation amount increases.

When the P mode or the non-P mode is set, the ECU 42 adjusts the flow rate of exhaust gas introduced to the heat receiving passage 23 by executing control for adjusting the opening degree of the open/close valve 40 on the basis of the open/close valve opening degree map 54. Thus, the ECU 42 variably sets the amount of heat of exhaust gas, transferred to the heat receiving substrates 30. By adjusting the flow rate of exhaust gas introduced to the heat receiving passage 23, the flow rate of exhaust gas emitted from the bypass passage 25 is also adjusted.

Thus, when the P mode is set, flow rate control is executed such that, as the accelerator operation amount increases, the flow rate of exhaust gas flowing through the heat receiving passage 23 reduces as compared to that in the non-P mode.

When the non-P mode is set, the ECU 42 adjusts the opening degree of the open/close valve 40 such that the flow rate of exhaust gas flowing through the heat receiving passage 23 reduces as compared to that when the state of charge of the auxiliary battery 44, which is charged with electric power generated by the thermoelectric conversion modules 28, is smaller than a predetermined level on the basis of the detected information from the SOC sensor 49 on the condition that the state of charge of the auxiliary battery 44 is larger than or equal to the predetermined level.

The ECU 42 adjusts the opening degree of the open/close valve 40 such that the flow rate of exhaust gas flowing through the heat receiving passage 23 reduces as compared to that when the coolant temperature is lower than a predetermined temperature on the basis of the detected information from the coolant temperature sensor 46 on the condition that the coolant temperature is higher than or equal to the predetermined temperature.

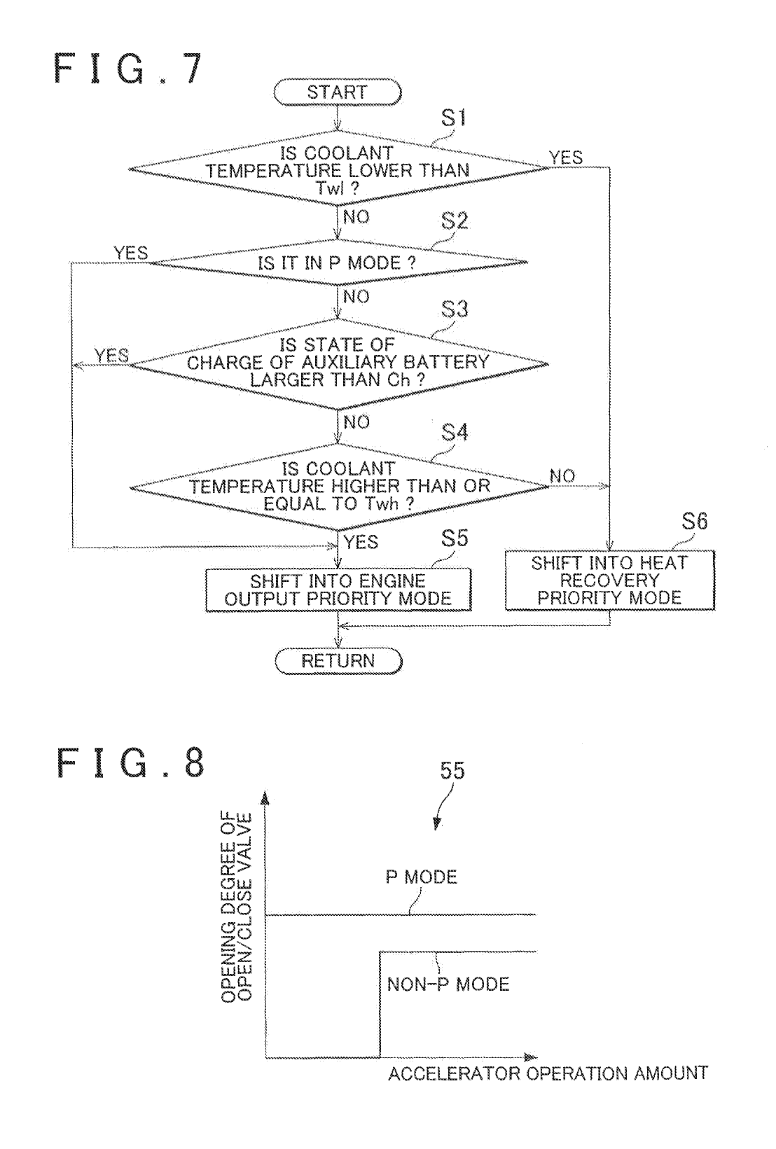

Next, open/close control over the open/close valve 40 will be described with reference to the flowchart of FIG. 7. The flowchart of FIG. 7 is an open/close control program for the open/close valve 40, stored in the ROM 42b of the ECU 42. The open/close control program is executed by the CPU 42a.

In FIG. 7, the ECU 42 determines whether the coolant temperature is lower than a predetermined temperature Twl on the basis of the detected information from the coolant temperature sensor 46 (step S1). The predetermined temperature Twl is, for example, set for a warm-up temperature. When the ECU 42 has determined that the coolant temperature is lower than or equal to the predetermined temperature Twl, the ECU 42 determines that the engine is in warm-up operation and shifts into a heat recovery priority mode (step S6), and then controls the open/close valve 40 to a closing side.

Specifically, at the time of a cold start of the engine 1, all the catalysts 12, 13 and coolant of the engine 1 are at low temperatures (about outside air temperature). When the engine 1 is started in this state, low-temperature exhaust gas is emitted from the engine 1 to the exhaust pipe 11 via the exhaust manifold 9 as the engine 1 is started, and the two catalysts 12, 13 are increased in temperature by the exhaust gas.

In addition, coolant is returned to the engine 1 via the bypass pipe 20, the upstream-side pipe 16 and the downstream-side pipe 18 without passing through the radiator 15. Thus, warm-up operation is performed.

That is, at the time of a cold start of the engine 1, for example, the engine 1 is operated at an idle and the pressure of exhaust gas is low, so the ECU 42 sets the open/close valve 40 in a closed state with the use of the actuator 41 by outputting the drive signal to the actuator 41.

Therefore, exhaust gas introduced from the exhaust pipe 11 to the bypass passage 25 of the inner pipe 22 is introduced to the heat receiving passage 23, coolant flowing through the coolant pipe 29 is increased in temperature by the exhaust gas passing through the heat receiving passage 23, and warm-up of the engine 1 is facilitated.

The flow rate of exhaust gas introduced to the heat receiving passage 23 increases, so the amount of heat of exhaust gas, which acts on the heat receiving substrates 30, increases, the temperature difference between the heat receiving substrates 30 and the heat dissipating substrates 31 on which coolant acts increases, and the amount of electric power generated by the thermoelectric conversion modules 28 increases.

When the ECU 42 has determined in step S1 that the coolant temperature is higher than or equal to the predetermined temperature Twl, the ECU 42 determines that warm-up of the engine has been completed, and determines whether it is in the P mode (step S2).

When the power switch 51 is selected, the ECU 42 determines that it is in the P mode, and shifts into an engine output priority mode (step S5). In the engine output priority mode, the open/close valve opening degree map 54 stored in the ROM 42b is consulted on the basis of the detected information from the accelerator operation amount sensor 53, and the open/close valve 40 is opened at an opening degree larger than that in the non-P mode on the basis of the accelerator operation amount.

When the open/close valve 40 is opened, the bypass passage 25 communicates with the tail pipe 27, the flow rate of exhaust gas flowing through the heat receiving passage 23 reduces or exhaust gas almost does not flow through the heat receiving passage 23, and most of exhaust gas is directly emitted to the tail pipe 27 through the bypass passage 25.

Therefore, coolant flowing through the coolant pipe 29 is not increased in temperature by high-temperature exhaust gas. In addition to this, the thermoelectric conversion modules 28 is not exposed to high-temperature exhaust gas and do not receive heat damage, so it is possible to prevent damage to the thermoelectric conversion modules 28.

At this time, fluid communication between the delivery pipe 14 and the bypass pipe 20 is interrupted by the thermostat 21, so coolant delivered from the engine 1 through the delivery pipe 14 is delivered to the upstream-side pipe 16 via the radiator 15. Therefore, low-temperature coolant is supplied from the upstream-side pipe 16 to the engine 1 via the coolant pipe 29 and the downstream-side pipe 18, with the result that it is possible to improve the cooling performance of the engine 1.

In the P mode, the opening degree of the throttle valve 4 is adjusted to a larger opening degree for the same accelerator operation amount in the non-P mode, and the torque of the engine 1 increases. Therefore, by increasing the opening degree of the open/close valve 40 as compared to that in the non-P mode, the back pressure of exhaust gas flowing through the bypass passage 25 does not increase, and a decrease in the output performance of the engine 1 is suppressed.

On the other hand, when the normal switch 50 or the eco switch 52 is selected in step S2, the ECU 42 determines that the non-P mode is set, and determines whether the state of charge of the auxiliary battery 44 is larger than or equal to a predetermined level Ch on the basis of the detected information from the SOC sensor 49 (step S4).

The predetermined level is, for example, set to an upper limit value of the state of charge of the auxiliary battery 44, and the ECU 42 shifts into the engine output priority mode when the ECU 42 has determined that the state of charge of the auxiliary battery 44 is larger than or equal to the predetermined level Ch (step S4).

In the engine output priority mode, the amount of exhaust gas flowing through the heat receiving passage 23 is small or almost no exhaust gas flows through the heat receiving passage 23, so the amount of heat of exhaust gas, which acts on the heat receiving substrates 30, is small, and the amount of electric power generated by the thermoelectric conversion modules 28 is small.

When the ECU 42 has determined in step S4 that the state of charge of the auxiliary battery 44 is smaller than the predetermined level Ch, the ECU 42 determines whether the coolant temperature is higher than or equal to the predetermined temperature Twh on the basis of the detected information from the coolant temperature sensor 46 (step S4). The predetermined temperature Twh corresponds to a predetermined temperature according to the invention.

The predetermined temperature Twh is, for example, set to a temperature at which the engine 1 may overheat. The ECU 42 shifts into the engine output priority mode when the ECU 42 has determined that the coolant temperature is higher than or equal to the predetermined temperature Twh (step S4).

In the engine output priority mode, the flow rate of exhaust gas flowing through the heat receiving passage 23 is small or almost no exhaust gas flows through the heat receiving passage 23. Therefore, the amount of heat of exhaust gas, which acts on the heat receiving substrates 30, is small, so there is no possibility that coolant is boiled by high-temperature exhaust gas.

In step S4, the ECU 42 shifts into the heat recovery priority mode when the ECU 42 has determined that the coolant temperature is lower than the predetermined temperature Twh (step S6).

In the heat recovery priority mode, the ECU 42 opens the open/close valve 40 at a smaller opening degree than that when the amount of charge of the auxiliary battery 44 is larger than or equal to the predetermined level Ch and the coolant temperature is higher than or equal to the predetermined temperature Twh. Therefore, the flow rate of exhaust gas flowing from the bypass passage 25 to the heat receiving passage 23 increases, and the amount of heat of exhaust gas, which acts on the heat receiving substrates 30, increases, so the amount of electric power generated by the thermoelectric conversion modules 28 increases.

In this way, the ECU 42 and actuator 41 of the thermoelectric generator 17 according to the present embodiment adjust the opening degree of the open/close valve 40 such that the flow rate of exhaust gas flowing through the heat receiving passage 23 reduces as compared to that in the non-P mode when the P mode in which the torque of the engine 1 is increased is selected after completion of warm-up of the engine 1.

Therefore, it is possible to increase the flow rate of exhaust gas flowing through the bypass passage 25 by increasing the opening degree of the bypass passage 25. Therefore, it is possible to prevent an increase in the back pressure of the engine 1, so it is possible to suppress a decrease in the output performance of the engine 1.

The ECU 42 and the actuator 41 adjust the opening degree of the open/close valve 40 such that the flow rate of exhaust gas flowing through the heat receiving passage 23 increases as compared to that in the P mode when the non-P mode is selected after completion of warm-up of the engine 1, so it is possible to increase the amount of heat of exhaust gas, which acts on the heat receiving substrates 30. Therefore, it is possible to improve the power generation efficiency of the thermoelectric conversion modules 28.

The ECU 42 and the actuator 41 do not adjust the opening degree of the open/close valve 40 such that the flow rate of exhaust gas flowing through the heat receiving passage 23 reduces as compared to that in the non-P mode even when the P mode is selected before completion of warm-up of the engine 1, so it is possible to prevent a decrease in the amount of heat of exhaust gas, which acts on the heat receiving substrates 30. Therefore, it is possible to facilitate heat exchange between exhaust gas and coolant, so it is possible to achieve early warm-up of the engine 1.

The ECU 42 and the actuator 41 according to the present embodiment variably set the amount of heat of exhaust gas, transferred to the heat receiving substrates 30, on the basis of the accelerator operation amount when the non-P mode or the P mode is selected. The ECU 42 executes flow rate control such that, when the P mode is set, the flow rate of exhaust gas flowing through the heat receiving passage 23 reduces as compared to that in the non-P mode as the accelerator operation amount increases.

Therefore, when the engine 1 rotates at a high speed and operates at a high load, it is possible to prevent an increase in the back pressure of the engine 1, so it is possible to further suppress a decrease in the output performance of the engine 1. Thus, it is possible to thermoelectrically generate electric power while maintaining the output performance of the engine 1.

The ECU 42 and the actuator 41 according to the present embodiment adjust the opening degree of the open/close valve 40 such that the flow rate of exhaust gas flowing through the heat receiving passage 23 reduces as compared to that when the state of charge of the auxiliary battery 44 is smaller than the predetermined level Ch on the condition that the non-P mode is selected and the state of charge of the auxiliary battery 44 is larger than or equal to the predetermined level Ch.

Therefore, for example, when the state of charge of the auxiliary battery 44 is an upper limit value, it is possible to reduce the amount of heat of exhaust gas, which acts on the heat receiving substrates 30, so it is possible to prevent useless charging operation.

The ECU 42 and the actuator 41 adjust the opening degree of the open/close valve 40 such that the flow rate of exhaust gas flowing through the heat receiving passage 23 reduces as compared to that when the coolant temperature is lower than the predetermined temperature Twh on the condition that the coolant temperature is higher than or equal to the predetermined temperature Twh.

Therefore, when the coolant temperature becomes higher than or equal to the predetermined temperature Twh and there is a possibility that coolant boils, it is possible to reduce the amount of heat of exhaust gas, which acts on the heat receiving substrates 30, so it is possible to prevent overheat of the engine 1 by preventing boiling of coolant.

The exhaust pipe of the thermoelectric generator 17 according to the present embodiment includes the inner pipe 22 having the bypass passage 25 to which exhaust gas emitted from the engine 1 is introduced and the outer pipe 24 provided coaxially with the inner pipe 22 and having the heat receiving passage 23 that communicates with the bypass passage 25 and that is formed between the outer pipe 24 and the inner pipe 22.

The heat receiving substrates 30 of the thermoelectric conversion modules 28 of the thermoelectric generator 17 face the outer pipe 24, the heat dissipating substrates 31 face the coolant pipe 29 provided coaxially with the outer pipe 24, and the open/close valve 40 is provided at the inner pipe 22 and is configured to adjust the flow rate of exhaust gas flowing through the heat receiving passage 23 by adjusting the opening degree of the bypass passage 25.

Thus, the thermoelectric generator 17 is able to increase the amount of heat that acts on the heat receiving substrates 30 through an increase in the flow rate of exhaust gas introduced to the heat receiving passage 23 of the outer pipe 24 by reducing the opening degree of the bypass passage 25 of the inner pipe 22 with the use of the open/close valve 40, so it is possible to improve the power generation efficiency of the thermoelectric conversion modules 28.

By increasing the opening degree of the bypass passage 25 with the use of the open/close valve 40, it is possible to increase the flow rate of exhaust gas emitted from the bypass passage 25, so it is possible to suppress a decrease in the exhaust emission performance of the engine 1 by decreasing the back pressure of the engine 1.

In the thermoelectric generator 17, the inner pipe 22, the outer pipe 24 and the coolant pipe 29 are provided coaxially with one another, so it is possible to reduce the size of the thermoelectric generator 17, and it is possible to improve the vehicle mountability of the thermoelectric generator 17.

The open/close valve opening degree map is not limited to the open/close valve opening degree map shown in FIG. 6. For example, as shown by an open/close valve opening degree map 55 in FIG. 8, the accelerator operation amount in the P mode may be associated with the opening degree of the open/close valve 40 such that the open/close valve 40 is fully open irrespective of the accelerator operation amount.

The accelerator operation amount in the non-P mode may be associated with the opening degree of the accelerator operation amount such that the open/close valve 40 is fully closed in a range in which the accelerator operation amount is small and the opening degree of the open/close valve 40 is kept at a set opening degree in a range in which the accelerator operation amount is large. In the present embodiment, the opening degree of the bypass passage 25 is adjusted with the use of the open/close valve 40 as a regulating valve; however, the regulating valve is not limited to the open/close valve.

### Second Embodiment

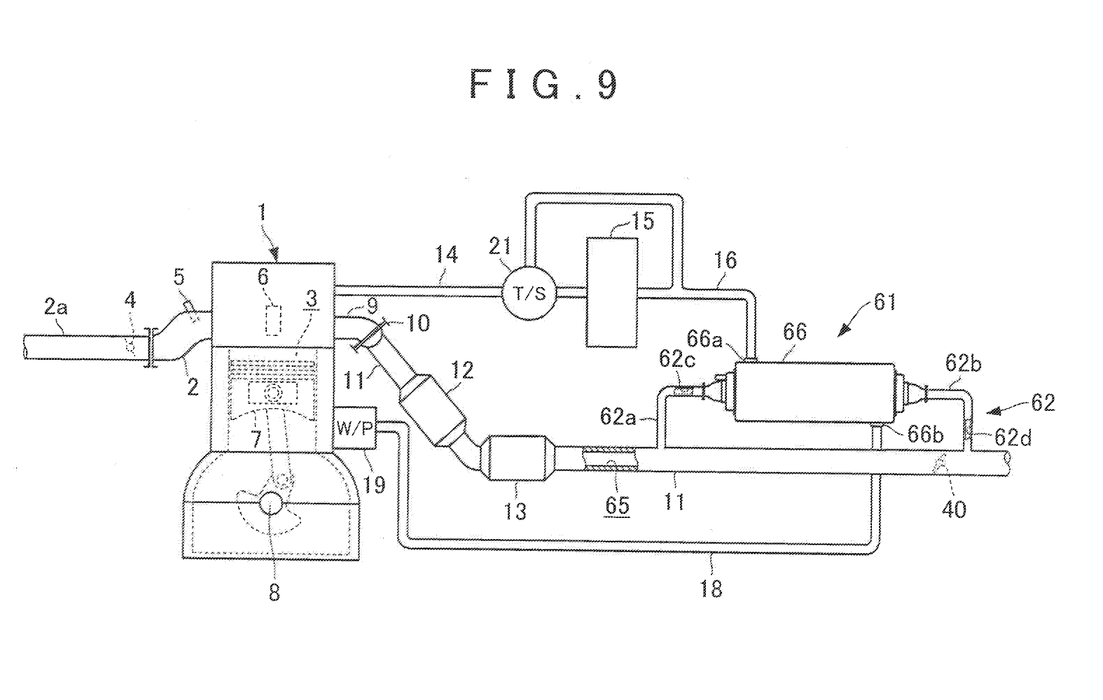

FIG. 9 to FIG. 11 are views that show a thermoelectric generator according to a second embodiment of the invention. The present embodiment differs from the first embodiment in only the configuration of the thermoelectric generator, and the control mode of the present embodiment is the same as that of the first embodiment. Therefore, like reference numerals denote the same components as those of the first embodiment, and the description thereof is omitted. Description will be made with reference to the control block diagram shown in FIG. 5.

In FIG. 9, a thermoelectric generator 61 is provided in the exhaust system of the engine 1. The thermoelectric generator 61 is connected to a bypass pipe 62 bypassed from the exhaust pipe 11.

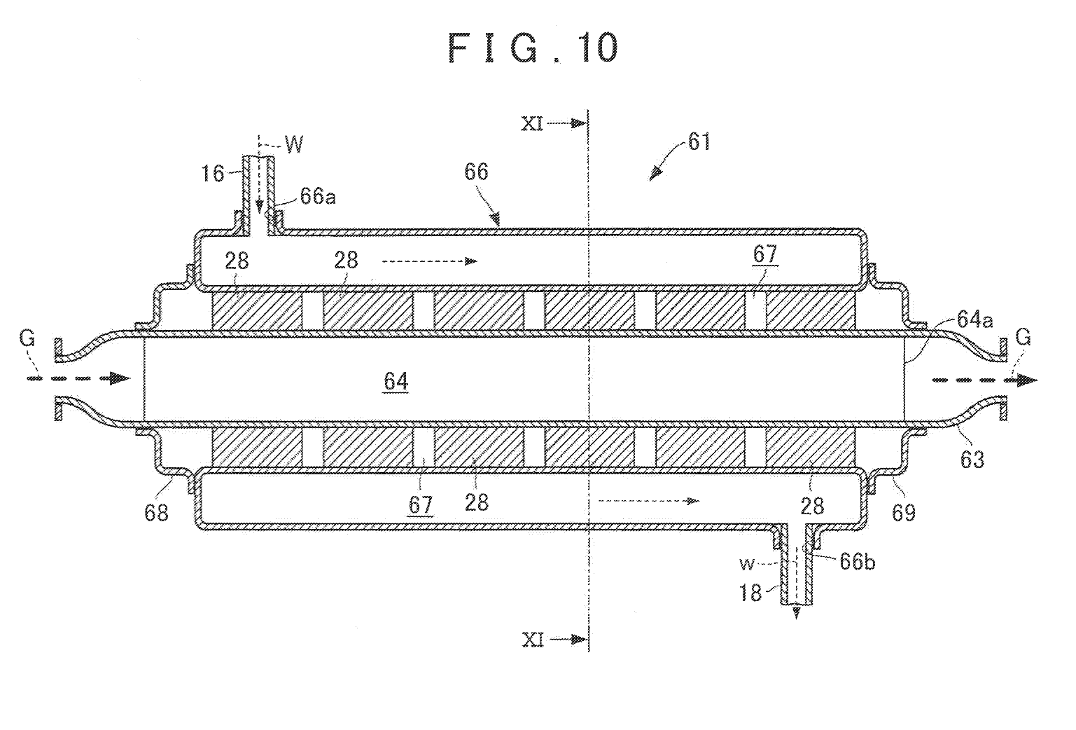

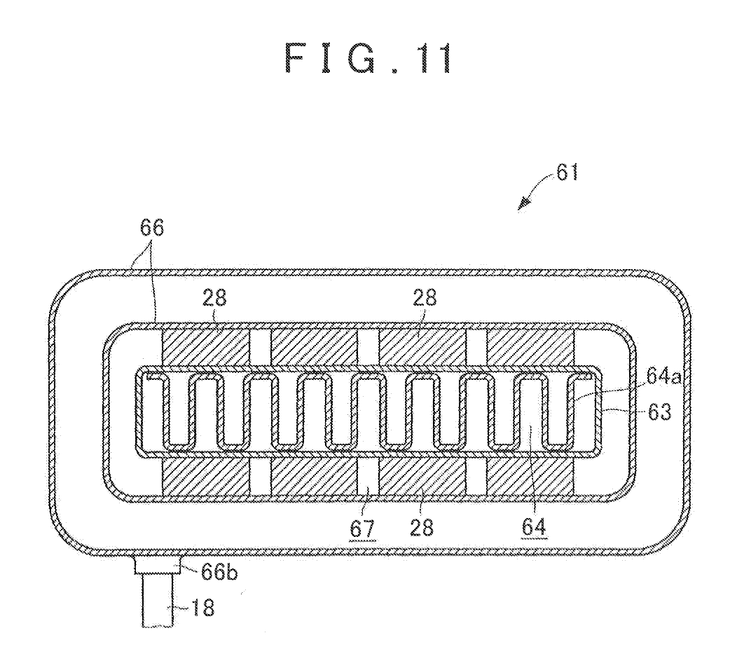

As shown in FIG. 10 and FIG. 11, the thermoelectric generator 61 includes an exhaust pipe 63 to which exhaust gas G is introduced. The exhaust gas G serves as high-temperature fluid emitted from the engine 1. The upstream end of the exhaust pipe 63 is connected to an upstream pipe portion 62a of the bypass pipe 62. The downstream end of the exhaust pipe 63 is connected to a downstream pipe portion 62b of the bypass pipe 62. An exhaust pipe according to the invention is formed of the exhaust pipe 11, the bypass pipe 62 and the exhaust pipe 63.

An exhaust passage 64 is formed inside the exhaust pipe 63. The exhaust gas G is introduced from an exhaust passage 65 (see FIG. 9) to the exhaust passage 64 via an exhaust passage 62c. The exhaust passage 65 is formed inside the exhaust pipe 11. The exhaust passage 62c is formed inside the upstream pipe portion 62a of the bypass pipe 62. The exhaust passage 64 emits the exhaust gas G to the exhaust passage 65 of the exhaust pipe 11 through an exhaust passage 62d formed inside the downstream pipe portion 62b of the bypass pipe 62.

Therefore, the exhaust gas G emitted from the engine 1 to the exhaust passage 64 of the exhaust pipe 63 through the exhaust passage 65 of the exhaust pipe 11 is emitted to the outside through the exhaust passage 65 of the exhaust pipe 11 again. In the present embodiment, the exhaust pipe 11 constitutes a first exhaust pipe, and the bypass pipe 62 and the exhaust pipe 63 constitute a second exhaust pipe. The exhaust passage 65 constitutes a first exhaust passage, and the exhaust passage 64, the exhaust passage 62c and the exhaust passage 62d constitute a second exhaust passage.

The thermoelectric generator 61 includes the plurality of thermoelectric conversion modules 28 and a cylindrical coolant pipe 66. The plurality of thermoelectric conversion modules 28 are arranged in the exhaust direction of the exhaust gas G. The coolant pipe 66 serves as a cooling pipe, and is provided coaxially with the exhaust pipe 63. The configuration of each thermoelectric conversion module 28 is the same as that of FIG. 3. In FIG. 10 and FIG. 11, each of the thermoelectric conversion modules 28 is simplified by omitting the heat receiving substrate 30, the heat dissipating substrate 31, the N-type thermoelectric conversion elements 32, the P-type thermoelectric conversion elements 33 and the electrodes 34a, 34b; however, the heat receiving substrates 30 face the exhaust pipe 63 and are in contact with the exhaust pipe 63, and the heat dissipating substrates 31 face the coolant pipe 66 and are in contact with the coolant pipe 66.

A comb-shaped heat transfer member 64a is provided in the exhaust passage 64 of the exhaust pipe 63. The heat transfer member 64a is bent along the width direction of the exhaust pipe 63 and extends in the longitudinal direction of the exhaust pipe 63, and is in contact with the inner periphery of the exhaust pipe 63 such that upper and lower end bent portions face the heat receiving substrates 30.

Therefore, heat of exhaust gas flowing through the exhaust passage 64 propagates through the heat transfer member 64a and is efficiently transferred to the heat receiving substrates 30. The coolant pipe 66 includes a coolant introduction portion 66a and a coolant drain portion 66b. The coolant introduction portion 66a is coupled to the upstream-side pipe 16. The coolant drain portion 66b is coupled to the downstream-side pipe 18.

In the coolant pipe 66, the coolant drain portion 66b is provided on the downstream side in the exhaust direction with respect to the coolant introduction portion 66a such that the coolant W serving as cooling medium introduced from the coolant introduction portion 66a to the coolant pipe 66 flows in the same direction as the exhaust direction of the exhaust gas G. Therefore, the coolant W flows in the same direction as the flow of the exhaust gas G flowing through the exhaust pipe 63.

In the coolant pipe 66, the coolant drain portion 66b may be provided on the upstream side in the exhaust direction with respect to the coolant introduction portion 66a such that coolant introduced from the coolant introduction portion 66a to the coolant pipe 66 flows in the direction opposite to the exhaust direction of the exhaust gas G.

As shown in FIG. 9, the open/close valve 40 that is controlled by the actuator 41 is provided at the exhaust pipe 11 as in the case of the first embodiment. The open/close valve 40 is provided between the upstream pipe portion 62a and downstream pipe portion 62b of the bypass pipe 62, and is pivotably connected to the exhaust pipe 11 so as to open or close the exhaust pipe 11.

As shown in FIG. 10 and FIG. 11, a space between the exhaust pipe 63 and the coolant pipe 66 forms a module chamber 67 as a hermetically sealed space in which the thermoelectric conversion modules 28 are arranged. That is, as shown in FIG. 10, a plate 68 is provided so as to span between the upstream side of the exhaust pipe 63 and the coolant pipe 66, and the upstream end of the module chamber 67 is closed by the plate 68.

A plate 69 is provided so as to span between the downstream side of the exhaust pipe 63 and the coolant pipe 66, and the downstream end of the module chamber 67 is closed by the plate 69. Thus, the module chamber 67 is formed of a hermetically sealed space surrounded by the outer peripheral portion of the exhaust pipe 63, the inner peripheral portion of the coolant pipe 66 and the plates 68, 69.

In the thermoelectric generator 61 according to the present embodiment, the ECU 42 and the actuator 41 increase the opening degree of the open/close valve 40 such that the flow rate of exhaust gas flowing through the exhaust passage 64 reduces as compared to that in the non-P mode when the P mode in which the torque of the engine 1 is increased is selected after completion of warm-up of the engine 1, so it is possible to increase the flow rate of exhaust gas flowing through the exhaust passage 65. Therefore, it is possible to prevent an increase in the back pressure of the engine 1, so it is possible to suppress a decrease in the output performance of the engine 1.

The ECU 42 and the actuator 41 reduce the opening degree of the open/close valve 40 such that the flow rate of exhaust gas flowing through the exhaust passage 64 increases as compared to that in the P mode when the non-P mode is selected after completion of warm-up of the engine 1, so it is possible to increase the amount of heat of exhaust gas, which acts on the heat receiving substrates 30. Therefore, it is possible to improve the power generation efficiency of the thermoelectric conversion modules 28.

The ECU 42 and the actuator 41 do not increase the opening degree of the open/close valve 40 such that the flow rate of exhaust gas flowing through the exhaust passage 64 reduces as compared to that in the non-P mode even when the P mode is selected before completion of warm-up of the engine 1, so it is possible to prevent a decrease in the amount of heat of exhaust gas, which acts on the heat receiving substrates 30. Therefore, it is possible to facilitate heat exchange between exhaust gas and coolant, so it is possible to achieve early warm-up of the engine 1.

The ECU 42 and the actuator 41 according to the present embodiment variably set the amount of heat of exhaust gas, transferred to the heat receiving substrates 30, on the basis of the accelerator operation amount when the non-P mode or the P mode is selected. The ECU 42 executes flow rate control such that, when the P mode is set, the flow rate of exhaust gas flowing through the exhaust passage 64 reduces as compared to that in the non-P mode as the accelerator operation amount increases.

Therefore, when the engine 1 rotates at a high speed and operates at a high load, it is possible to prevent an increase in the back pressure of the engine 1, so it is possible to further suppress a decrease in the output performance of the engine 1. Thus, it is possible to thermoelectrically generate electric power while maintaining the output performance of the engine 1.

The ECU 42 and the actuator 41 according to the present embodiment increase the opening degree of the open/close valve 40 such that the flow rate of exhaust gas flowing through the exhaust passage 64 reduces as compared to that when the state of charge of the auxiliary battery 44 is smaller than the predetermined level Ch on the condition that the non-P mode is selected and the state of charge of the auxiliary battery 44 is larger than or equal to the predetermined level Ch.

Therefore, for example, when the state of charge of the auxiliary battery 44 is an upper limit value, it is possible to reduce the amount of heat of exhaust gas, which acts on the heat receiving substrates 30, so it is possible to prevent useless charging operation.

The ECU 42 and the actuator 41 increase the opening degree of the open/close valve 40 such that the flow rate of exhaust gas flowing through the exhaust passage 64 reduces as compared to that when the coolant temperature is lower than the predetermined temperature Twh on the condition that the coolant temperature is higher than or equal to the predetermined temperature Twh.

Therefore, when the coolant temperature becomes higher than or equal to the predetermined temperature Twh and there is a possibility that coolant boils, it is possible to reduce the amount of heat of exhaust gas, which acts on the heat receiving substrates 30, so it is possible to prevent overheat of the engine 1 by preventing boiling of coolant.

In the present embodiment, the opening degree of the exhaust passage 64 is adjusted with the use of the open/close valve 40 as a regulating valve; however, the regulating valve is not limited to the open/close valve. Each of the thermoelectric generators 17, 61 may be applied to a hybrid vehicle that uses an internal combustion engine and a motor as drive sources.

As described above, the thermoelectric generator according to the invention has advantageous effects such that it is possible to change the opening degree of the regulating valve on the basis of the operation mode of the internal combustion engine, it is possible to suppress a decrease in the output performance of the internal combustion engine and it is possible to improve power generation efficiency, so it is useful as, for example, a thermoelectric generator that thermoelectrically generates electric power by utilizing heat of exhaust gas emitted from the internal combustion engine.

1. A thermoelectric generator that can be mounted on an internal combustion engine, the thermoelectric generator comprising:
a selecting device configured to select a first operation mode and a second operation mode in which a torque of the internal combustion engine for the same accelerator operation amount is adjusted to a torque larger than that in the first operation mode
an exhaust pipe including a first exhaust passage to which exhaust gas emitted from the internal combustion engine is introduced and a second exhaust passage that communicates with the first exhaust passage;
a thermoelectric conversion module including a high-temperature portion and a low-temperature portion, the high-temperature portion facing the second exhaust passage, the low-temperature portion facing a cooling pipe through which cooling medium flows, the thermoelectric conversion module being configured to thermoelectrically generate electric power on the basis of a temperature difference between the high-temperature portion and the low-temperature portion;
a regulating valve provided at the exhaust pipe and configured to adjust a flow rate of the exhaust gas flowing through the second exhaust passage by adjusting an opening degree of the first exhaust passage; and
a controller configured to adjust an opening degree of the regulating valve such that the flow rate of the exhaust gas flowing through the second exhaust passage reduces as compared to that in the first operation mode, on the condition that the second operation mode is selected by the selecting device after completion of warm-up of the internal combustion engine.

2. The thermoelectric generator according to claim 1, wherein
the controller is configured to variably set the flow rate of the exhaust gas introduced to the second exhaust passage on the basis of the accelerator operation amount when one of the first operation mode and the second operation mode is selected, and
the controller is configured to execute flow rate control such that the flow, rate of the exhaust gas flowing through the second exhaust passage reduces as compared to that in the first operation mode as the accelerator operation amount increases when the second operation mode is set.

3. The thermoelectric generator according to claim 1, wherein
the controller is configured to adjust the opening degree of the regulating valve such that the flow rate of the exhaust gas flowing through the second exhaust passage reduces as compared to that when a state of charge of a battery is smaller than a predetermined level, on the condition that the first operation mode is selected and a state of charge of a battery, which is charged with electric power generated by the thermoelectric generator, is larger than or equal to the predetermined level.

4. The thermoelectric generator according to claim 1, wherein the cooling medium flowing through the cooling pipe is coolant that cools the internal combustion engine, and
the controller is configured to adjust the opening degree of the regulating valve such that the flow rate of the exhaust gas flowing through the second exhaust passage reduces as compared to that when temperature of the coolant is lower than a predetermined temperature, on the condition that the temperature of the coolant is higher than or equal to the predetermined temperature.

5. The thermoelectric generator according to claim 1, wherein the exhaust pipe includes a first exhaust pipe and a second exhaust pipe, the first exhaust pipe having the first exhaust passage, the second exhaust pipe provided coaxially with the first exhaust pipe, the second exhaust pipe having the second exhaust passage that communicates with the first exhaust passage,
the high-temperature portion of the thermoelectric conversion module faces the second exhaust pipe, the low-temperature portion faces the cooling pipe provided coaxially with the second exhaust pipe, and
the regulating valve is provided at the first exhaust pipe and configured to adjust the flow rate of the exhaust gas flowing through the second exhaust passage by adjusting the opening degree of the first exhaust passage.
